(19) United States
(12) Patent Application Publication
(10) Pub. No.: US 2004/0105316 A1
(43) Pub. Date: Jun. 3, 2004

(54) Low program power flash memory array and related control method

(76) Inventors: Ching-Sung Yang, Chang-Hua Hsien (TW); Ching-Hsiang Hsu, Hsin-Chu City (TW)

Correspondence Address: NAIPO (NORTH AMERICA INTERNATIONAL PATENT OFFICE), P.O. BOX 506, MERRIFIELD, VA, 22116, US

(21) Appl. No.: 10/065,910

(22) Filed: Nov. 28, 2002

(51) Int. Cl. G11C 5/00

(52) U.S. Cl. 365/189.09

(57) ABSTRACT

A flash memory array and related method for programming, erasing, and reading. The memory includes: a plurality of memory cells, each memory cell having a gate, a drain, a source, and a body; a plurality of word lines and body lines. The bodies of the memory cells whose gates are connected to a same word line are connected to a same body line, and the body lines are isolated from each other such that different body lines can be driven to have different voltages. When the memory programs, erases, and reads data, the different body lines are driven to different voltage.

### BACKGROUND OF INVENTION

1. Field of the Invention

The present invention relates to a flash memory and related programming, erasing, and reading methods of the flash memory, and more particularly, to a flash memory whose body is controlled by different voltages and related control methods.

2. Description of the Prior Art

Most modern information appliances, such as personal data assistants and personal computers, comprise non-volatile memory for storing information and digital data. In the non-volatile memory, a flash memory, capable of electrically writing, programming, and erasing data, has become one of the most important data storage devices in modern information technologies.

Please refer to FIG. 1, which is a schematic diagram of a prior art flash memory 10 circuit. The flash memory 10 comprises a plurality of metal oxide semiconductor (MOS) transistors. Each MOS transistor serves as a memory unit. The flash memory 10 further comprises two bit lines B0, B1 and six word lines W0 to W5, disposed corresponding to a disposition of the MOS transistors. Two word line circuits 12A, 12B control voltages at the six word lines W0 to W5. The flash memory 10 further comprises a source line CS. The voltage at the source line CS is controlled by a source circuit 16.

Each MOS transistor of the flash memory 10 comprises a gate, a drain, and a source. MOS transistors T1 through T8 (shown in FIG. 1) of the flash memory 10 are described as an example. The drains of the transistors T1, T2 are connected to the bit line B0 via a node Np1. The drains of the transistors T3, T4 are connected to the bit line B0 via a node Np3. Likewise the drains of the transistors T5, T6 are connected to the bit line B1 via a node Np4 and the drains of the transistors T7, T8 are connected to the bit line B1 via a node Np6. The gates of the transistors T1, T5 are connected to the word line W0. The gates of the transistors T2, T6 are connected to the word line W1. Likewise, the gates of the transistors T3, T7 are connected to the word line W2 and the gates of the transistors T4, T8 are connected to the word line W3. The sources of the transistors T1, T5 are connected to the source line CS via a node NP7. The sources of the transistors T2, T3 are connected to the source line CS via a node NP2. Likewise, the sources of the transistors T6, T7 are connected to the source line CS via a node NP5. A common-source disposition of the plurality of the transistors T1 through T8 forms a NOR flash memory array of the flash memory 10.

Please refer to FIG. 2, which corresponds to a cross-section diagram along a line 3A-3A of the flash memory 10 shown in FIG. 1. Each transistor of the flash memory 10 is formed on a p-substrate L1. An n-doped area L2b serves as the drains of the transistors T5, T6. Another n-doped area L2d serves as the drains of the transistors T7, T8. A conductive layer L3, which is connected to the two n-doped areas L2b, L2d, is the bit line B1. Two n-doped areas L2a, L2e are respectively the sources of the transistors T5, T8. An n-doped area L2c represents the sources of the transistor T6, T7. Four conductive layers L4a, L4b, L4c, and L4d, all disposed inside an oxide layer L7, are respectively the gates of the transistors T5 through T8. Another four conductive layers LSa to L5d, also disposed inside the oxide layer L7, are respectively floating gates of the transistors T5 through T8. The floating gate of each transistor is capable of storing charge even if the flash memory 10 is not connected to a source of electricity.

Please refer to FIG. 3A and FIG. 3B. FIG. 3A is a cross-sectional electrical connection diagram along the line 3A-3A of the flash memory 10 shown in FIG. 1. FIG. 3B corresponds to a cross-sectional electrical connection diagram along a line 3B-3B of the flash memory 10 shown in FIG. 1. Shown in FIG. 3A, the n-doped areas L2b, L2d (the drains of the transistors T5 through T8) are connected to the bit line B1, the n-doped areas L2a, L2c, and L2e (the sources of the transistors T5 through T8) are connected to the source line CS, and the conductive layers L4a to L4d (the gates of the transistors T5 through T8) are respectively connected to the word lines W0 to W3. FIG. 3B shows that an n-doped area L20 and the n-doped area L2b (the drains of the transistors T1, T5) are respectively connected to the bit lines B0 and B1, and two field oxides L6a, L6b are used to isolate an electrical interference existing between the transistors T1 and T5.

Additionally, each transistor of the prior art flash memory 10 further comprises a body. Because the transistors of the flash memory 10 are all formed on the p-substrate L1, the p-substrate L1 thus can be deemed as the body of each transistor. Since all the bodies of the transistors of the flash memory 10 are electrically connected, voltages of the bodies of the plurality of transistors of the flash memory 10 are identical.

As is known to those skilled in the art, a transistor of the flash memory 10 is capable of storing one-bit of data, whose value corresponds to the amount of charge stored in a floating gate of the transistor. A transistor whose floating gate stores a large amount of charge has a high threshold voltage. On the contrary, a threshold voltage of a transistor whose floating gate stores a small amount of charges is low. That is, if applied by an identical driving voltage, a transistor whose floating gate stores a large amount of charge is hard to be actuated, but a transistor whose floating gate stores a small amount of charge is easy to be actuated. In other words, because injecting charge into or removing charges from a floating gate of a transistor can change the amount of charge stored in the floating gate of the transistor, measuring a current flowing through a source of the transistor can reveal a data bit stored in the floating gate of the transistor.

Please refer to FIG. 4A, FIG. 4B, and to FIG. 1. FIG. 4A, FIG. 4B are schematic diagrams of voltages at electrodes of a memory unit of the flash memory 10 and of neighboring memory units of the memory unit when the memory unit is executing a programming process. FIG. 4A is an electrical connection cross-sectional diagram along the line 3A-3A of the transistor T5 shown in FIG. 1. FIG. 4B is an electrical connection cross-sectional diagram along the line 3B-3B of the transistor T5, T1 shown in FIG. 1.

The programming process is accomplished by injecting charge into a floating gate of a transistor. A process to inject charge into the floating gate LSa of the transistor T5 of the flash memory 10 is described as follows. First the bit line B1 is set to five volts and the bit line B0 is set to 0 volts with the bit line circuit 14A, 14B, as shown in FIG. 4B. Set the word line W0 (being connected to the gate L4a of the transistor T5) at 10 volts and the source line CS at 0 vols. Thus, the transistor T5 actuates and actuated currents will flow across the drain of the transistor T5 and the source of the transistor T5. Finally, part of the charge of the actuated currents passes through the oxide layer L7 and then arrives at the floating gate.

The above programming process of the flash memory 10 is a so-called hot-electron-injection programming process of the flash memory 10. However, the programming process described above to induce the hot-electron-injection effect has some drawbacks. The first one is that a 10 volts driving voltage at the word line W0 and a five volts driving voltage at the bit line B1 are too high to adapt the flash memory 10 to a modern electrical circuit because most modern electrical circuits use a low level voltage as a driving voltage. The low level driving voltage of a modern electrical circuit cannot drive the flash memory 10. The second drawback is that if the actuated currents flowing across the n-doped area L2b and the n-doped area L2a are too high, the flash memory 10 consumes a large quantity of power during a programming process. The third drawback is that a leakage current will flow toward the n-doped area L20, impacting the electrical interference isolation existing between the transistor T1 and the transistor T5. This is because the n-doped area L20, L2b, and the field oxide L6a equivalently form a field transistor FT. When the transistor T5 is in a programming process (the voltage of the drain n-doped area L2b is kept at five volts and the voltage of the drain n-doped area L20 of the transistor T1 is kept at 0 volts by the bit line B0), the equivalent field transistor FT is forward biased and generates the leakage current, which results in a so-called program disturbance.

Please refer to FIG. 5, which is a schematic diagram of voltages at electrodes of the transistor T5, which is executing an erasing process. The gate conductive layer L4a of the transistor T5 is kept at −10 volts, the bit line B1 is floating, and the source line is kept at five volts. Then charge of the floating gate (conductive layer L5a) of the transistor T5 will move through the oxide layer L7 to the n-doped area L2a due to the Fowler-Nordheim effect.

Please refer to FIG. 6A, FIG. 6B, and to FIG. 1. FIG. 6A, FIG. 6B are schematic diagrams of voltages at electrodes of corresponding memory units of the flash memory 10 shown in FIG. 1 when the flash memory 10 is executing a reading process. FIG. 6A corresponds to an electrical connection cross-sectional diagram along the line 3A-3A of the flash memory 10 shown in FIG. 1. FIG. 6B shows an electrical connection cross-sectional diagram along the line 3B-3B of the flash memory 10 shown in FIG. 1.

How the flash memory 10 reads data stored in the transistor T5 is described as follows. The word line W0 of the flash memory 10 keeps the gate of the transistor T5 at four volts and keeps the remaining word lines W1 to W5 all at 0 volts. When the reading process of the flash memory 10 starts, a voltage of the bit line B1 corresponding to the transistor T5 will be charged up to one volt, a voltage of the bit line B0 is kept at 0 volts and a voltage of the source line CS is also kept at 0 volts. If the floating gate of the transistor T5 has stored some charge (that is the threshold voltage of the transistor T5 is high), even though the voltage of the gate is at four volts, the transistor T5 will not actuate, keeping the voltage of the bit line B1 at 1 volt. On the contrary, if the floating gate of the transistor T5 does not store any charge, the transistor T5 will actuate, discharging the bit line B1 and making the voltage of the bit line B1 equal the voltage 0 volts of the source line CS. The flash memory 10 is capable of reading data stored in the transistor T5 by determining the voltage change occurred at the bit line B1. However, the above-mentioned program disturbance still occurs when the flash memory 10 is executing the reading process. That is a leakage current will affect the electrical interference isolation existing between the transistor T5 and its neighboring transistors.

Shown in FIG. 6, a transistor T6, neighboring the transistor T5, still conducts a leakage current flowing across the drain n-doped area L2b and the source n-doped area L2c even if the transistor T5 is not actuated. The voltage of the bit line B1 is thus decreased due to the leakage current. The unexpected voltage drop existing at the bit line B1 results in the flash memory 10 being hard to read out data stored in the transistor T5. Shown in FIG. 6B, a field transistor FT, formed between the transistor T5 and transistors in the vicinity, is easy to actuate a current flowing across the n-doped area L2b and the n-doped area L20. The actuated current results in a voltage change occurring at the bit line B1.

Because the plurality of transistors in the flash memory 10 are all formed directly on the p-substrate, which means that the bodies of the plurality of transistors are tied together, the electrical interference existing between the plurality of transistors cannot be isolated by controlling the voltage of the bodies of the plurality of transistors. This uncontrolled electrical interference affects the performance of the flash memory 10. Furthermore, the flash memory 10 needs an extra self-aligned source etching (SAS) process to implement the common-source structure. The SAS process is complicated and time-consuming, and therefore the cost of the flash memory 10 is inevitably increased.

### SUMMARY OF INVENTION

It is therefore a primary objective of the claimed invention to provide a memory to solve the above-mentioned problems.

According to the claimed invention, the memory includes a plurality of first memory cells. Each first memory cell has a gate, a body, a source, and a drain. The gate of each first memory cell is connected to a first word line. The body of each first memory cell is connected to a first body line. Each first memory cell is used for storing a data bit and the first memory cell is capable of generating a current corresponding to the data bit. The current flowing across the drain of the first memory cell and the source of the first memory cell corresponds to a voltage at the first word line.

The memory further includes a plurality of second memory cells. Each second memory cell has a gate, a body, a source, and a drain. The gate of each second memory cell is connected to a second word line. The body of each second memory cell is connected to a second body line. Each second memory cell is used for storing a data bit, and for providing a current corresponding to the data bit and flowing across the drain of the second memory cell and the source of the second memory cell according to a voltage at the second word line.

The memory further includes a bit line circuit, which is connected to the drains of the plurality of the first memory cells and to the drains of the plurality of the second memory cells, and a source circuit, which is connected to the sources of the plurality of the first memory cells and to the sources of the plurality of the second memory cells. In the memory, the first body line is not electrically connected to the second body line to make a voltage at the first body line be different from a voltage at the second body line.

It is an advantage of the claimed invention that the memory can form the common source structure with the n-well, rather than the SAS manufacturing process. Additionally, each body line can be individually biased, which results in a reduction of electrical interference existing between the plurality of transistors and a reduction of programming or reading disturbance caused by leakage currents.

These and other objectives of the claimed invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a schematic diagram of a prior art flash memory circuit.

FIG. 2 is a cross-sectional diagram along a line 3A-3A of the flash memory shown in FIG. 1.

FIG. 3A is a cross-sectional electrical connection diagram along the line 3A-3A of the flash memory shown in FIG. 1.

FIG. 3B is a cross-sectional electrical connection diagram along a line 3B-3B of the flash memory shown in FIG. 1.

FIG. 4A is an electrical connection cross-sectional diagram along the line 3A-3A of the transistor T5 shown in FIG. 1.

FIG. 4B is an electrical connection cross-sectional diagram along the line 3B-3B of the transistor T5, T1 shown in FIG. 1.

FIG. 5 is a schematic diagram of voltages at electrodes of the transistor T5.

FIG. 6A is an electrical connection cross-sectional diagram along the line 3A-3A of the flash memory shown in FIG. 1.

FIG. 6B is an electrical connection cross-sectional diagram along the line 3B-3B of the flash memory shown in FIG. 1.

FIG. 7 is a schematic diagram of a circuit of a memory according to the present invention.

FIG. 8 is a cross-sectional structure diagram along a line 9A-9A of the memory shown in FIG. 7.

FIG. 9A is a cross-sectional electrical connection diagram along a line 9A-9A of the memory shown in FIG. 7.

FIG. 9B is a cross-sectional electrical connection diagram along a line 9B-9B of the memory shown in FIG. 7 when a transistor is executing a programming process.

FIG. 10A is an electrical connection cross-sectional diagram along the line 9A-9A of the memory shown in FIG. 7 when a transistor is executing a programming process.

FIG. 10B is another electrical connection cross-sectional diagram along the line 9B-9B of the memory shown in FIG. 7.

FIG. 11A is an electrical connection cross-sectional diagram along the line 9A-9A shown in FIG. 7 when a transistor is executing a first erasing process.

FIG. 11B is an electrical connection cross-sectional diagram along the line 9B-9B shown in FIG. 7 when a transistor is executing a first erasing process.

FIG. 12A is an electrical connection cross-sectional diagram along the line 9A-9A shown in FIG. 7 when a transistor is executing a second erasing process.

FIG. 12B is an electrical connection cross-sectional diagram along the line 9B-9B shown in FIG. 7 when a transistor is executing a second erasing process.

FIG. 13A is an electrical connection cross-sectional diagram along the line 9A-9A shown in FIG. 7 when a transistor is executing a first reading process.

FIG. 13B is an electrical connection cross-sectional diagram along the line 9B-9B shown in FIG. 7 when a transistor is executing a first reading process.

FIG. 14A is an electrical connection cross-sectional diagram along the line 9A-9A shown in FIG. 7 when a transistor is executing a second reading process.

FIG. 14B is an electrical connection cross-sectional diagram along the line 9B-9B shown in FIG. 7 when a transistor is executing a second reading process.

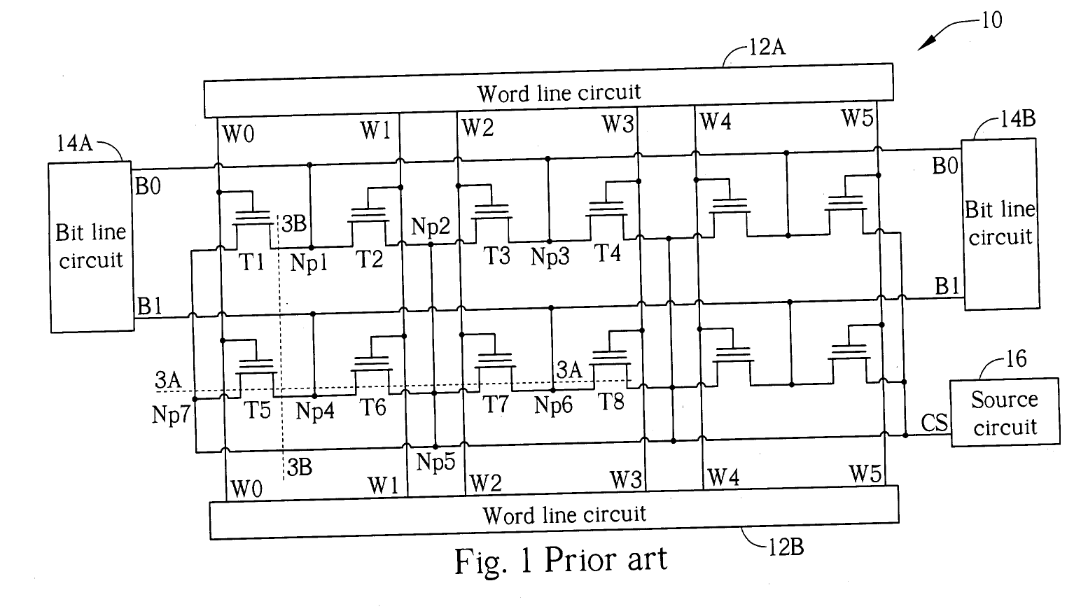

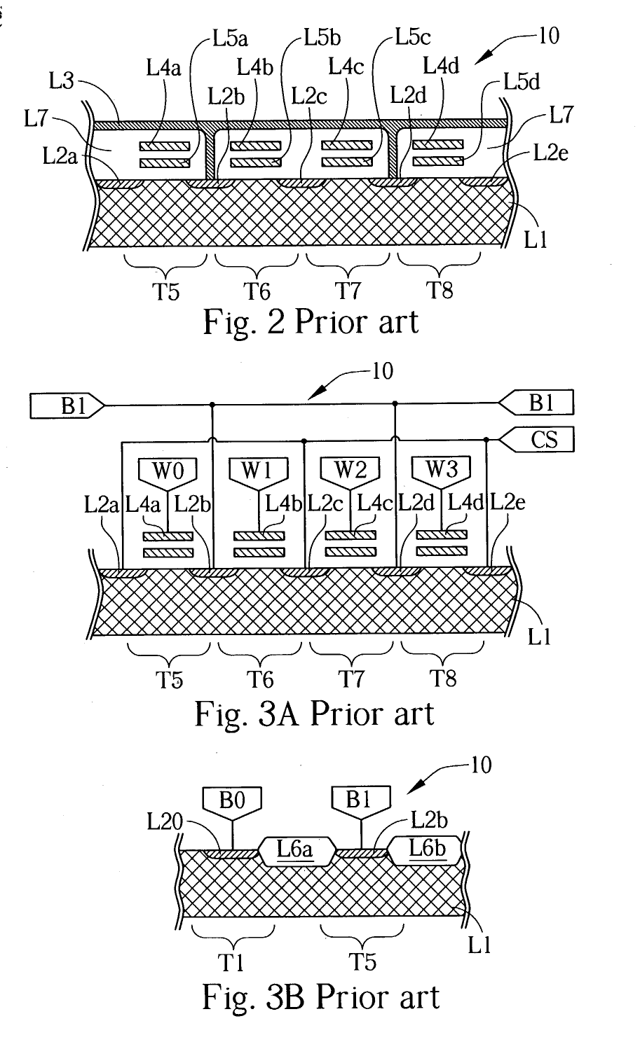

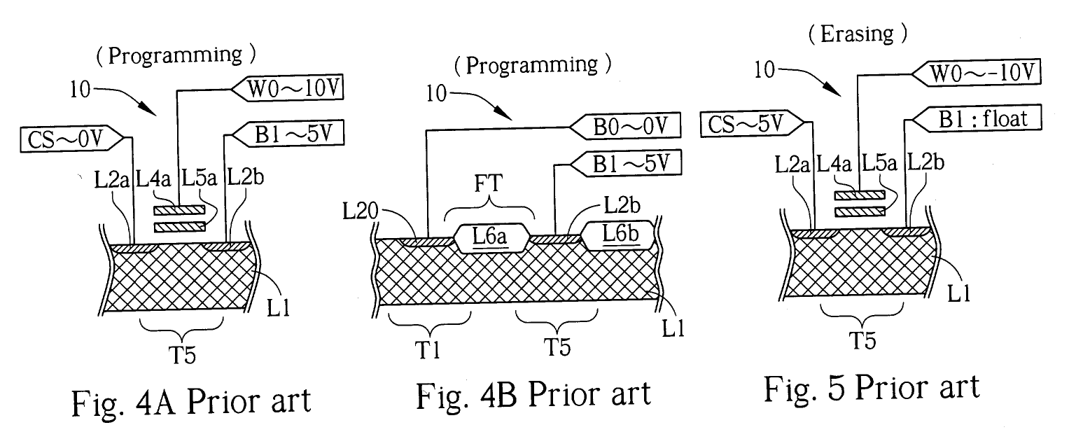

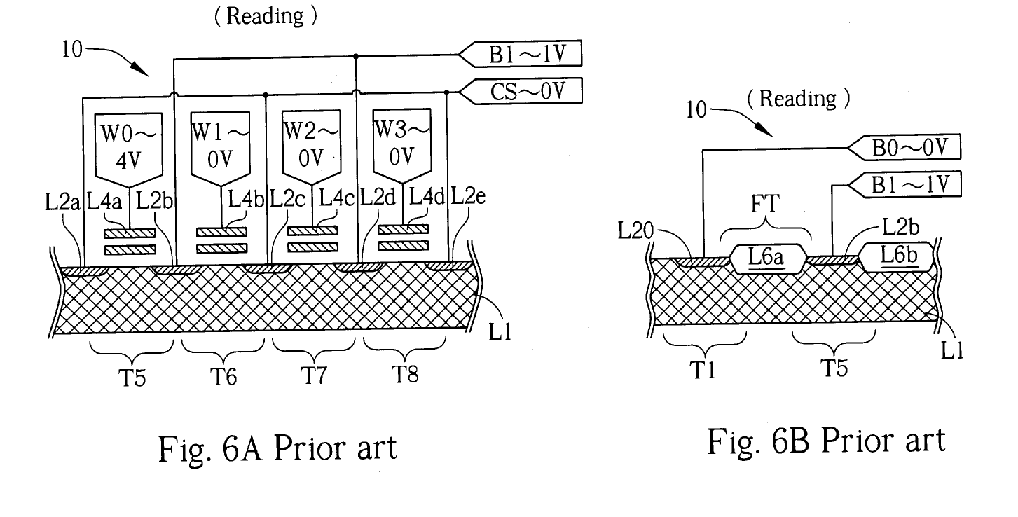

### DETAILED DESCRIPTION

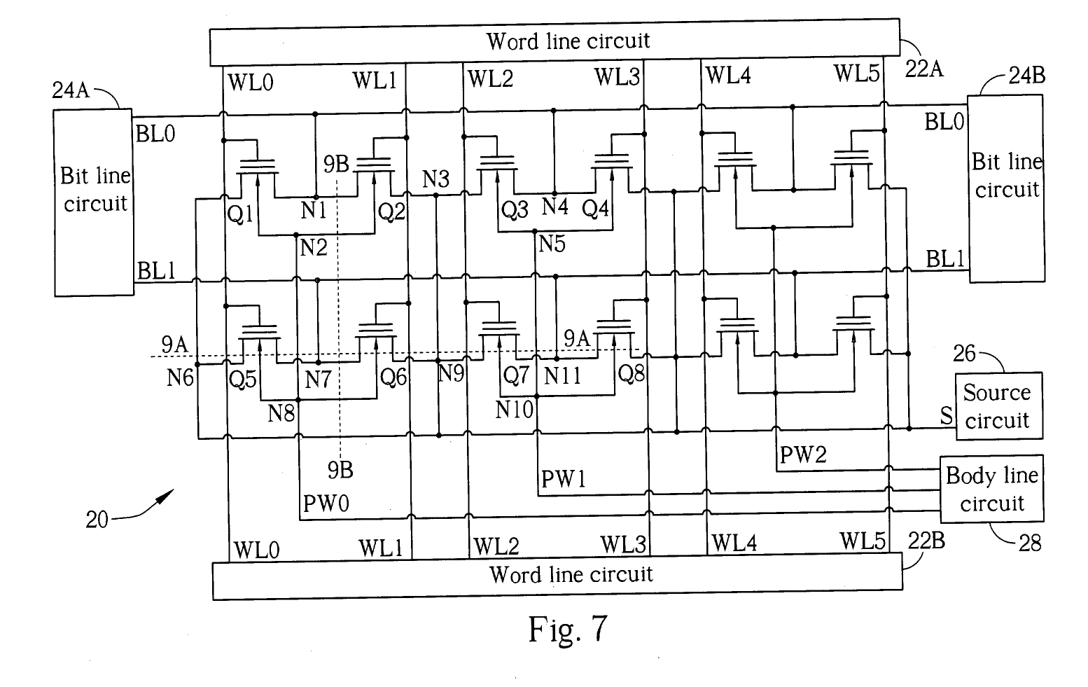

Please refer to FIG. 7, which is a schematic diagram of a circuit of a memory 20 according to the present invention. The memory 20 comprises a plurality of transistors serving as memory units. Each transistor of the plurality of transistors has a gate, a source, a drain, and a body. The memory 20 further comprises two bit lines BL0, BL1 corresponding to a two-row disposition of the plurality of transistors as shown in FIG. 7. The bit lines BL1, BL2 are respectively connected to the drains of the transistors disposed in the first row and to the drains of the transistors disposed in the second row. Two bit line circuit 24A, 24B (can comprise an address decoder circuit, a corresponding voltage driving circuit, or an access detecting amplifier, etc.) are respectively used to drive voltages of the bit lines BL0, BL1.

The memory 20 further comprises six word lines WL0 to WL5, which correspond to a six-column disposition of the plurality of transistors shown in FIG. 7, respectively connected to the gates of the transistors. Two word line circuits 22A, 22B are used to drive voltages of the six word lines WL0 to WL5. The memory 20 further comprises three body lines PW0 to PW2. The body line PW0 is connected to the bodies of the transistors Q1, Q2, Q5, Q6. The body line PW1 is connected to the bodies of the transistors Q3, Q4, Q7, Q8. The three body lines PW0, PW1, PW2 are driven by a body line circuit 28 respectively. A source line S connects the sources of the plurality of transistors and a source circuit 26. A more detailed connection description is described as follows.

Take the transistor Q1 as an example, the gate of the transistor Q1 is connected to the word line WL0. The drain of the transistor Q1 is connected to the bit line BL0 at node N1. The source of the transistor Q1 is connected to the source line S at node N6. The body of the transistor Q1 is connected to the body line PW0 at node N2.

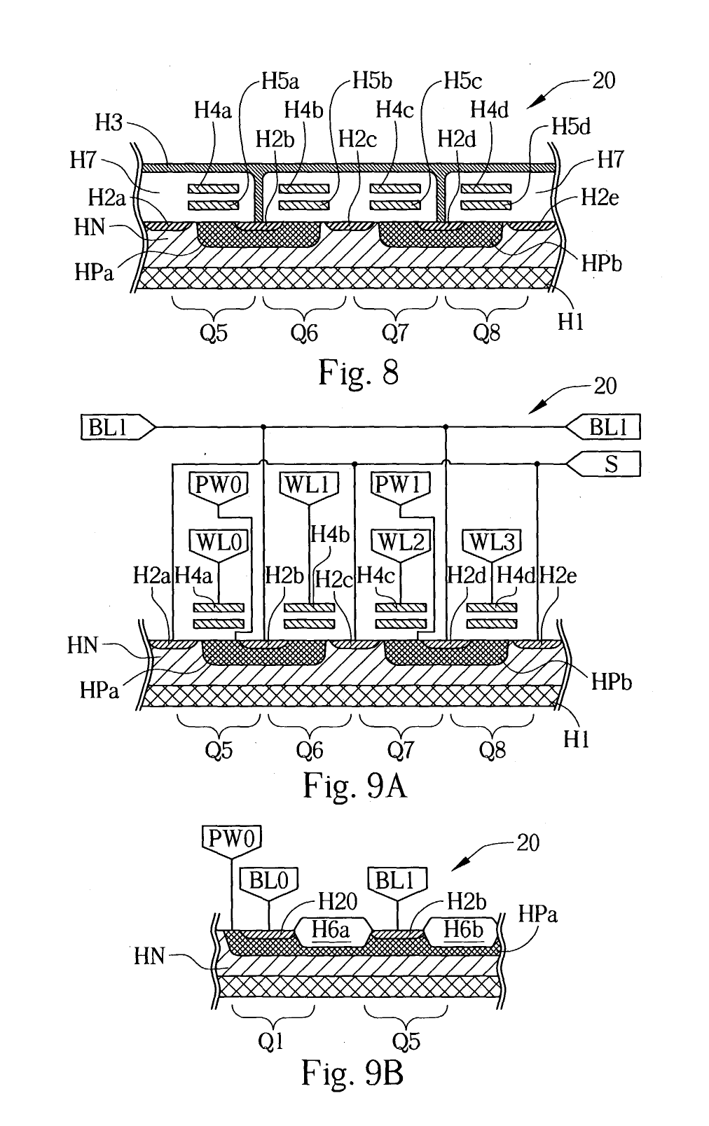

Please refer to FIG. 8 (and also to FIG. 7), which is a cross-sectional structure diagram along a line 9A-9A of the memory 20 shown in FIG. 7. The memory 20 is formed on an n-well HN, which is disposed on a p-substrate H1. Two p+ doped areas HPa, HPb are formed on the n-well HN. The p+ doped area HPa serves as the bodies of the transistors Q5, Q6, and as the body line PW0, which is parallel to the six word lines W0 to W5. Likewise, the p+ doped area HPb serves as the bodies of the transistors Q7, Q8, and as the body line PW1. Four conductive layers H4a, H4b, H4c, and H4d, all disposed inside an oxide layer H7, are respectively gates of the transistors Q5 to Q8. Four conductive layers H5a, HSb, H5c, and HSd, also formed inside the oxide layer H7, are respectively floating gates of the transistors Q5 to Q8. Each floating gate is capable of storing charge. An n+ doped area H2b serves as drains of the transistors Q5, Q6. Another n+ doped area H2d serves as drains of the transistors Q7, Q8. A conductive layer H3 is the bit line BL1. Four n+ doped areas H2a, H2c, and H2e form sources of the transistors Q5 to Q8 (the n+ doped area H2c is the sources of the transistors Q6, Q7). The sources of the plurality of transistors Q1 to Q8 are all connected to the n-well HN. The disposition of the plurality of transistors Q1 to Q8 forms an NOR memory array. The n-well HN is the source line S of the NOR memory array.

Please refer to FIG. 9A and FIG. 9B (also to FIG. 7). FIG. 9A is a cross-sectional electrical connection diagram along a line 9A-9A of the memory 20 shown in FIG. 7. FIG. 9B is a cross-sectional electrical connection diagram along a line 9B-9B of the memory 20 shown in FIG. 7. As described previously, the conductive layers H4a to H4d of the transistors Q5 to Q8 are sequentially connected to the word lines WL0 to WL3. The n+ doped areas H2b of the transistors Q5, Q6 and the n+ doped areas H2d of the transistors Q7, Q8 are connected to the bit line BL1. The n+ doped areas H2a, H2c, and H2e of the transistors Q5 to Q8 are all connected to the source line S. As shown in FIG. 9B, the p+ doped area HPa forms not only the bodies of the transistors Q5, Q6, but the body line PW0, which is parallel to the six word lines WL0 to WL5 and is connected to the bodies of transistor Q1, Q5. The n+ doped area H20 serves as the drain of the transistor Q1. The drain of the transistor Q1 is connected to the bit line BL0. Two field oxides H6a, H6b are used to isolate electrical interference existing between the transistors Q1, Q5.

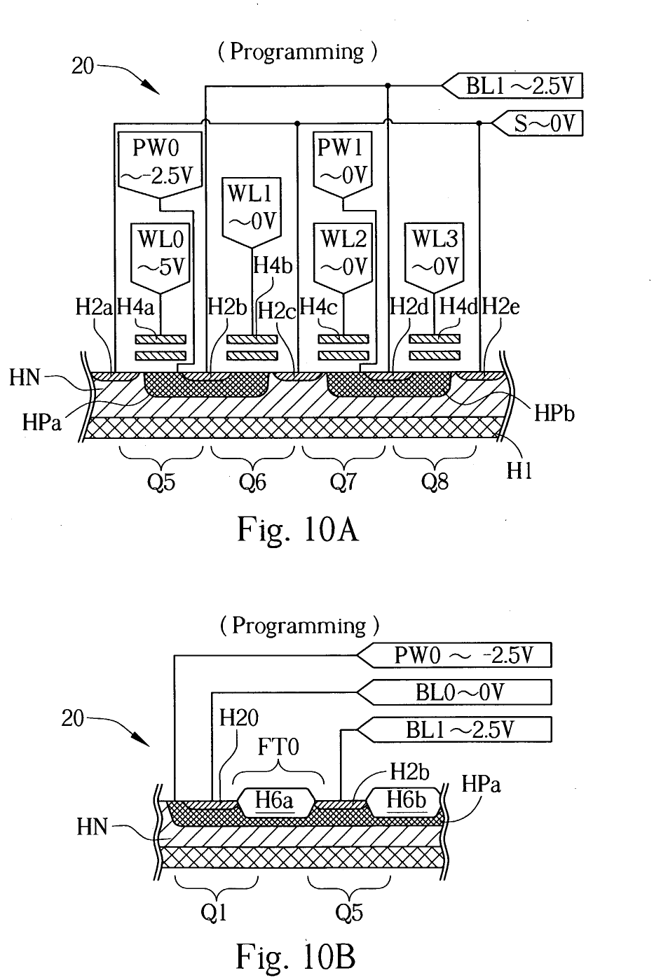

Please refer to FIG. 10A, FIG. 10b, and FIG. 7. FIG. 10A, FIG. 10B are schematic diagrams of voltages at electrodes of corresponding memory units of the memory 20 when the memory 20 is executing a programming process. FIG. 10A shows an electrical connection cross-sectional diagram along the line 9A-9A of the memory 20 shown in FIG. 7. FIG. 10B shows another electrical connection cross-sectional diagram along the line 9B-9B of the memory 20 shown in FIG. 7. The memory 20 of the present invention is capable of injecting charges into the floating gates of memory cells of the memory 20 with the hot-electron-injection programming process.

When the memory 20 is programming a transistor memory cell of the memory 20, the word line circuits 22A, 22B give a word line corresponding to the transistor a five volts bias voltage, and keep the remaining word lines at 0 volts; the bit line circuits 24A, 24B give a bit line corresponding to the transistor a 2.5 volts bias voltage, and keep the other bit line at 0 volts; a bias voltage of the body line of the transistor is 2.5 volts, and the remaining body lines are kept at 0 volts; the source line is also biased at 0 volts. For example, when the memory 20 is programming the transistor Q5, set word line WL0, which is connected to the gate of the transistor Q5, at five volts and the remaining word lines WL1 to WL5 at 0 volts, set the bit line BL1, which is connected to the drain of the transistor Q5, at 2.5 volts, and the other bit line at 0 volts, and set the body line PW0, which is connected to the transistor Q5, at 2.5 volts, and the remaining body lines PW1, PW2 at 0 volts. Thus, the transistor Q5 is actuated and an actuated current will flow across the drain of the transistor Q5 and the source of the transistor Q5. “Hot-electrons” in the actuated currents therefore inject into the floating gate (the conductive layer H5a shown in FIG. 8) of the transistor Q5. Please notice that the above-mentioned voltage levels (5, 2.5, 0, −2.5 volts) are only illustrated as an example, the actual voltage levels at the corresponding elements of the memory 20 are related to size, structure, and doping density in a variety of memories.

Advantages of the above programming process of the memory 20 are briefly described as follows. A negative voltage of the body line PW0 is capable of reducing the electrical interference existing between any two neighboring transistors. That is, the program disturbance occurring in the programming process of the prior art memory 10 will not occur in the programming process of the memory 20 of the present invention. Please refer to FIG. 10A again. To apply a negative voltage bias to the body line PW0 is equivalent to applying the negative voltage bias to the transistor Q6, which is not executing the programming process, and a threshold voltage of the transistor Q6 will raise due to a body effect, so the transistor Q6 is hard to be actuated, a leakage of the transistor Q6 is small, and thus the programming transistor Q5 will not affect operations of the transistor Q6. Likewise because the transistor Q5 and the transistor Q6 share a common body (also a common body line PW0, applying a negative voltage bias to the body line PW0 will raise a threshold voltage of the transistor Q5 and reduces a conductivity between the drain and the source of the transistor Q5.

Such a way can reduce power consumption of currents flowing across the drain and the source due to the hot-electron-injection-effect, and improve hot-electron floating gate injection efficiency. This is because that the negative voltage of the transistor Q5 will repel more electrons located between the drain and the source to flow toward and inject into the floating gate. Additionally, as shown in FIG. 10B, the field oxide H6a and the n-doped area H20, H2b form an equivalent field transistor FT0. When the transistor Q5 is executing the programming process, the negative voltage of the body line PWO also raises an equivalent threshold voltage of the field transistor FT0 due to the body effect. The raised threshold voltage of the field transistor FT corresponds to a low leakage current of the field transistor FT. Therefore, the electrical interference existing between the transistors Q5, Q1 is effectively isolated and the remaining transistors will not be affected by programming the transistor Q5. The negative voltage of the body line PW0 can keep a voltage difference between a gate conductive layer H4a and the p+ doped area Hpa at a constant level without raising a positive voltage level of the gate, making the programming process have a high hot-electron injection efficiency without a high positive voltage bias.

Furthermore, each memory cell transistor of the prior art memory 10 uses the whole substrate as a common body, the whole substrate meaning a large body equivalent capacitance, so it is difficult to change a voltage level of the large body equivalent capacitance, that is the voltage level of the body, to adapt to different voltage bias demand of the programming, the erasing, or the reading process. On the contrary, because the body lines of the memory 20 are separated, meaning a small body equivalent capacitance, and can be respectively driven by the body line circuit 28, a voltage level of each body can be changed rapidly to switch the memory 20 from an operating process, say the programming process, to another operating process, say the erasing process.

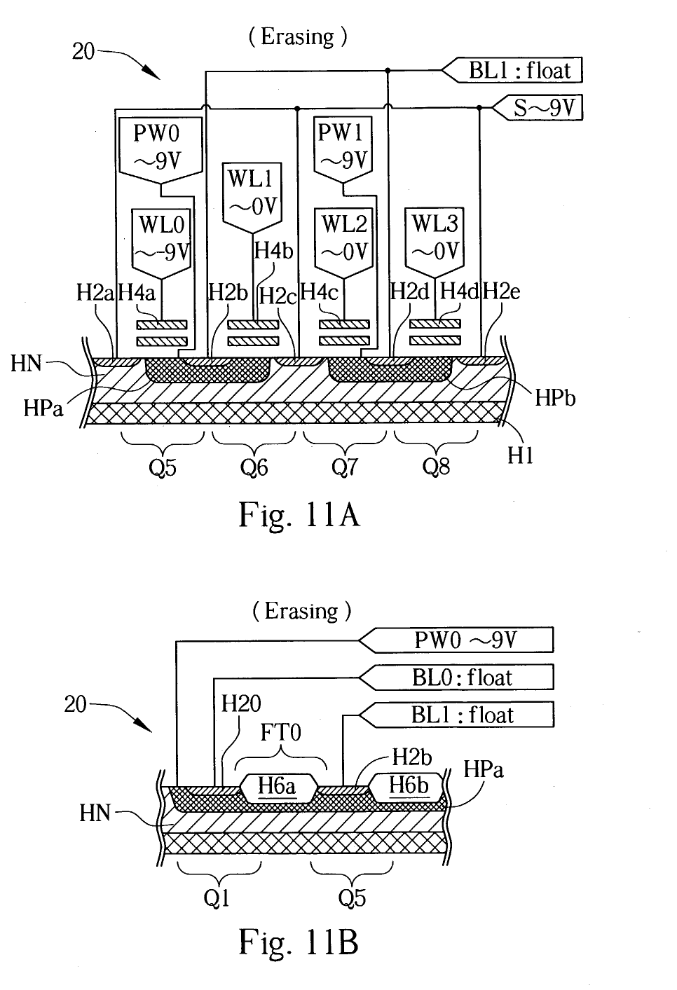

Please refer to FIG. 11A and FIG. 11B, which are schematic diagrams of voltages at electrodes of memory units of the flash memory 20 when the memory 20 is executing the erasing process. FIG. 11A is an electrical connection cross-sectional diagram along the line 9A-9A shown in FIG. 7. FIG. 11B is an electrical connection cross-sectional diagram along the line 9B-9B shown in FIG. 7.

The erasing process removes charge from a floating gate of a memory. When a memory cell transistor of the memory 20 is executing the erasing process, a voltage of a word line of the transistor is kept at 9 volts (the 9 volts is also called an erasing voltage level), the remaining word lines are kept at 0 volts, a body line corresponding to each memory cell is kept at 9 volts, a bit line connected to a drain of each memory cell is kept floating, and a common source line of the memory cells is kept at 9 volts. If the transistor Q5, shown in FIG. 11A and FIG. 11B, is executing the erasing process, the word line WL0 connected to the gate of the transistor Q5 is biased with 9 volts, the remaining word lines are kept at 0 volts, the body line connected to each transistor is biased with 9 volts, and the bit line of the drain of each transistor is kept floating. Thus, charges stored inside the floating gate of the transistor Q5 will be removed (erased) to the n+ doped area H2a due to the Fowler-Nordheim effect. The n+ doped area H2a of the source with a 9 volts bias voltage and the p+ doped area Hpa of the body prevent the p-n junction located between the source and the body from generating a leakage current, which inevitably consumes power.

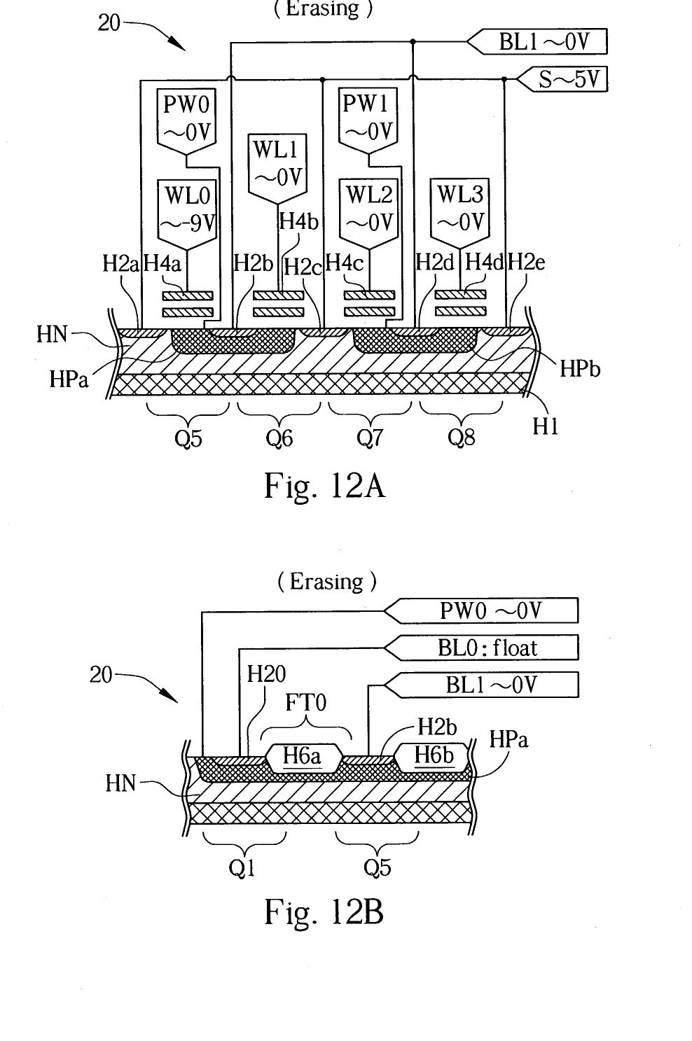

Please refer to FIG. 12A and FIG. 12B, which are schematic diagrams of voltages at electrodes of memory units of the flash memory 20 when the memory 20 is executing a second erasing process. FIG. 12A is an electrical connection cross-sectional diagram along the line 9A-9A shown in FIG. 7. FIG. 12B is an electrical connection cross-section diagram along the line 9B-9B shown in FIG. 7.

In this embodiment, a voltage of a word line of a transistor, which is executing the second erasing process, is kept at 9 volts, the remaining word lines are kept at 0 volts, a bit line corresponding to the transistor is kept at 0 volts, the remaining bit lines are kept floating, all body lines are kept at 0 volts, and the source line S is kept at 5 volts. If the transistor Q5, shown in FIG. 12A and FIG. 12B, is executing the second erasing process, the gate conductive layer H4a is biased with a 9 volts by the word line WL0, and the source line S is kept at 5 volts. Thus, charge stored inside the floating gate of the transistor Q5 will be removed (erased) to the n+ doped area H2a due to the Fowler-Nordheim effect.

Different charge volumes of memory cell transistors correspond to different threshold voltages. Two memory cell transistors respectively having different threshold voltage will actuate different current levels, even if both are applied with a same gate bias. Two different current levels represent two different data stored in the memory cell transistors.

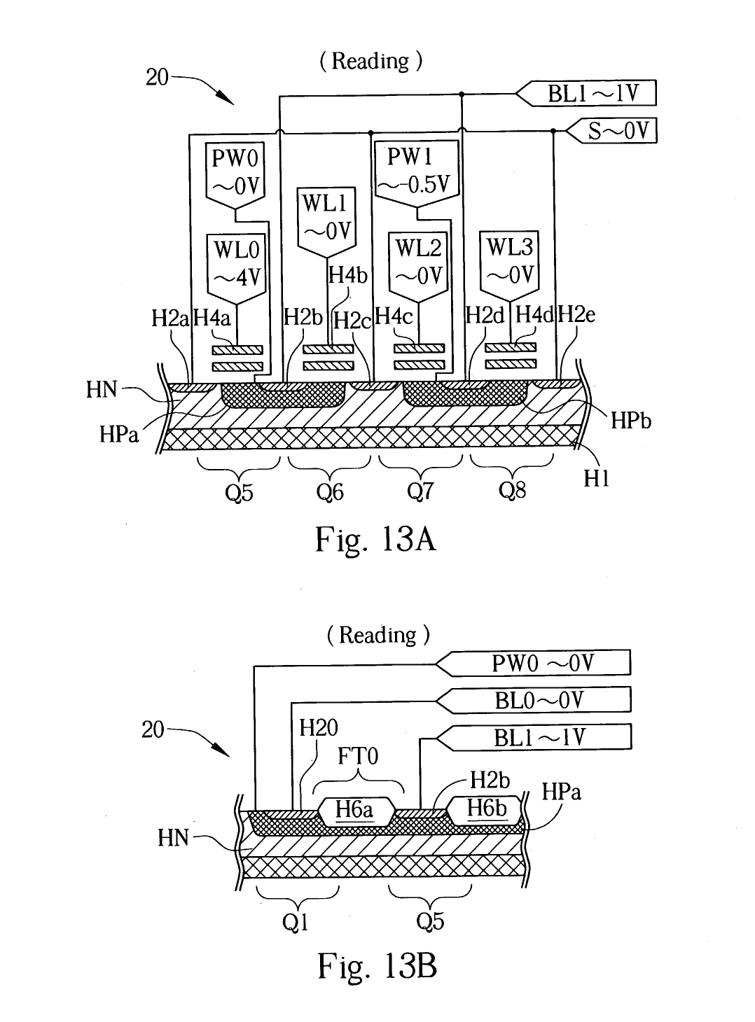

Please refer to FIG. 13A and FIG. 13B, which are schematic diagrams of voltages at electrodes of memory units of the flash memory 20 when the memory 20 is executing the reading process. FIG. 13A is an electrical connection cross-sectional diagram along the line 9A-9A shown in FIG. 7. FIG. 13B is an electrical connection cross-sectional diagram along the line 9B-9B shown in FIG. 7.

When a memory cell transistor of the memory 20 is executing the reading process, a voltage of a word line of a gate of the transistor is kept at 4 volts (the 4 volts is also called a reading voltage level), the remaining word lines are kept at 0 volts, a bit line of a drain of the transistor is charged up to 1 volt before the reading process starts, the remaining bit lines are kept at 0 volts, a body line of the transistor is kept at 0 volts, and the remaining body lines are all kept at 0.5 volt. If the transistor Q5, shown in FIG. 13A and FIG. 13B, is executing the erasing process, the bit line BL1 is charged up to 1 volt first, the remain bit lines are kept at 0 volts, the word line WL0 connected to the gate of the transistor Q5 is kept at 4 volts, the remaining word lines are kept at 0 volts, the body line connected to the transistor Q5 is kept at 0 volts, and the remaining body lines are kept at 0.5 volts. In the beginning of the reading process, because the voltage level of the bit line BL1 of the transistor Q5 has been charged to 1 volt, if the floating gate of the transistor Q5 has stored some charge, the threshold voltage of the transistor Q5 will raise and will not actuate, and the voltage level of the bit line BL1 is still kept at 1 volt. On the contrary, if the floating gate of the transistor Q5 does not store any charge, the word line with 4 volts voltage level actuates the transistor Q5. Thus, the bit line BL1 discharges charge to the source line through the actuated transistor Q5. Finally, the voltage level of the bit line BL1 drops from 1 volt 0 volts, which is the voltage level of the source line S. Therefore, data stored in the transistor Q5 can be read by determining whether the voltage level of the bit line BL1 is changed during the reading process. The threshold voltages of the remaining transistors can be raised by the negative biased body lines, such as the body line PW1 shown in FIG. 13A, because of the body effect.

High threshold voltage corresponds to low leakage current. That is the transistor Q5, which is executing the reading process, will not be affected by the remaining transistors. In the memory 20, because all the memory cell transistors are connected to the n-well NH by their source, the common source n-well providing a large equivalent capacitance, the voltage of the source line S will not change. When a transistor is executing the reading process, the corresponding bit line will be pulled low, and the large equivalent capacitance provided by the common source n-well NH forms a current sink, which will keep the voltage of the source line at a constant voltage level.

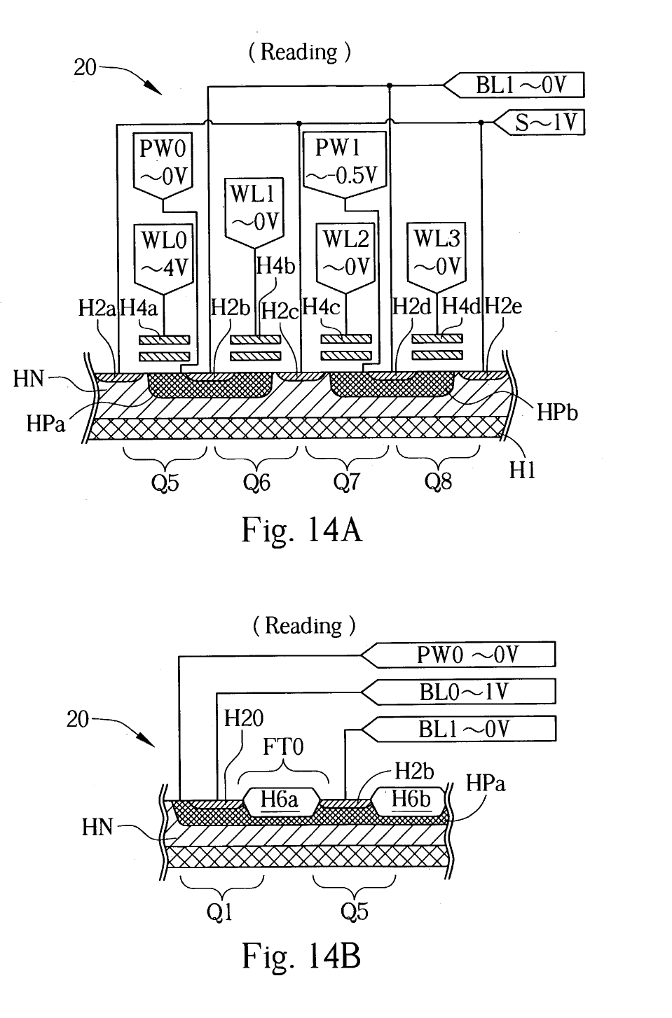

Please refer to FIG. 14A and FIG. 14B, which are schematic diagrams of voltages at electrodes of memory units of the flash memory 20 when the memory 20 is executing a second reading process. FIG. 14A is an electrical connection cross-sectional diagram along the line 9A-9A shown in FIG. 7. FIG. 14B is an electrical connection cross-sectional diagram along the line 9B-9B shown in FIG. 7.

In contrast to the first reading process, the second reading process charges the source line S up to 1 volt and discharges a drain of a transistor, which will execute the second reading process, down to 0 volts before the reading process starts. As shown in FIG. 14A and FIG. 14B, if the transistor Q5 is executing the second reading process, the bit line BL1, which corresponds to the drain of the transistor Q5, is discharged down to 0 volts, the remaining bit lines are kept at 1 volt, the source line S is kept at 1 volt, and the voltages of the remaining body lines and word lines are the same as those shown in FIG. 13a and FIG. 13B. If the floating gate of the transistor Q5 is stored with some charge, the threshold voltage of the transistor Q5 will raise and the transistor Q5 does not actuate. If the floating gate of the transistor Q5 does not store any charge, the transistor Q5 will actuate after the reading process begins. Then the source line S charges the bit line BL1 with the actuated transistor Q5, and the voltage of the bit line BL1 raises from 0 volts up to 1 volt, the voltage level of the source line S. In other words, whether or not a transistor is storing any charge can be determined by checking whether the voltage of the bit line corresponding to the transistor has been raised up to 1 volt. The common source n-well HN of the memory 20 also provides a large equivalent capacitance for a charging source, which stabilizes the voltage of the source line S. As soon as the reading process executing transistor has actuated, the source line S can charge the corresponding bit line quickly up to 1 v. In the above-mentioned two reading process embodiments, the voltages of all the body lines can also be kept at 0 volts.

In the prior art memory 10, because all the transistors are formed on a p-substrate, it is impossible to respectively control the bias voltage of the body line. Furthermore, the flash memory 10 needs an extra complicated and time-consuming self-aligned source etching (SAS) process to implement the common-source structure. In contrast to the prior art memory, the present invention memory forms the plurality of transistors on the n-well in the p-substrate, then forms a P-doped area as a body, an n-doped area as a source, and the n-well as a common source, and finally forms p-doped area body lines, which are parallel to each other, as a body line. The present invention memory can form the common source structure with the n-well, rather than the SAS manufacturing process. Additionally, each body line can be individually biased, which results in a reduction of electrical interference existing between the plurality of transistors and a reduction of programming or reading disturbance caused by leakage currents. In addition to the above-mentioned stack floating gate MOS transistors, the present invention memory can also use oxide-nitride-oxide (ONO) gate MOS transistors as memory cells.

Following the detailed description of the present invention above, those skilled in the art will readily observe that numerous modifications and alterations of the device may be made while retaining the teachings of the invention. Accordingly, the above disclosure should be construed as limited only by the metes and bounds of the appended claims.

What is claimed is:

1. A memory comprising:
a plurality of first memory cells; each first memory cell having a gate, a body, a source, and a drain; the gate of each first memory cell being connected to a first word line; the body of each first memory cell being connected to a first body line; wherein each first memory cell is used for storing a data bit and the first memory cell is capable of generating a current corresponding to the data bit, the current flowing across the drain of the first memory cell and the source of the first memory cell according to a voltage at the first word line;
a plurality of second memory cells; each second memory cell having a gate, a body, a source, and a drain; the gate of each second memory cell being connected to a second word line; the body of each second memory cell being connected to a second body line; wherein each second memory cell is used for storing a data bit, and for providing a current corresponding to the data bit and flowing across the drain of the second memory cell and the source of the second memory cell according to a voltage at the second word line;
a bit line circuit connected to the drains of the plurality of the first memory cells and to the drains of the plurality of the second memory cells; and
a source circuit connected to the sources of the plurality of the first memory cells and to the sources of the plurality of the second memory cells;
wherein the first body line is not electrically connected to the second body line to make a voltage at the first body line be different from a voltage at the second body line.

2. The memory of claim 1 wherein the bit line circuit comprises a plurality of bit lines; each bit line is connected to a drain of a corresponding first memory cell and to a drain of a corresponding second memory cell.

3. The memory of claim 1 further comprising a plurality of third memory cells; each third memory cell having a gate, a source, a drain, and a body; a gate of each third memory cell being connected to a third word line; the bodies of the plurality of the third memory cells being connected to the first body line.

4. The memory of claim 1 further comprising a plurality of fourth memory cells; each fourth memory cell having a gate, a source, a drain, and a body; the gates of the plurality of fourth memory cells being connected to a fourth word line; the bodies of the plurality of the fourth memory cells being connected to the second body line.

5. The memory of claim 1 wherein the source circuit is used for making a voltage at the source of each first memory cell equal a voltage at the source of each second memory cell.

6. The memory of claim 1 being installed on a p-substrate; the p-substrate having an n-well; the sources of the plurality of first memory cells and the sources of the plurality of second memory cells being installed on an n+ doped area of the n-well; the bodies of the plurality of first memory cells and the bodies of the plurality of second memory cells being installed on a p-doped area of the n-well.

7. The memory of claim 6 wherein all the p-doped areas of the plurality of the first memory cells are connected together to form the first body line.

8. The memory of claim 6 wherein all the p-doped areas of the plurality of the second memory cells are connected together to form the second body line.

9. The memory of claim 6 wherein the drain of each first memory cell is installed on an n+ doped area of the p-doped area of the first memory cell.

10. The memory of claim 6 wherein the drain of each second memory cell is installed on an n+ doped area of the p-doped area of the second memory cell.

11. The memory of claim 1 wherein each first memory cell and each second memory cell respectively further comprises a floating gate to form a stacked gate metal oxide semiconductor (MOS) transistor; the floating gate is used to store a charge of the data bit of the corresponding memory cell.

12. The memory of claim 1 wherein the plurality of first memory cells and the plurality of second memory cells are SONOS MOS transistors; each first memory cell and each second memory cell respectively further comprises an ONO charge storage layer for storing a charge of the data bit of the corresponding memory cell.

13. A method for controlling a memory; the memory comprising:
a plurality of first memory cells; each first memory cell having a gate, a body, a source, and a drain; the gate of each first memory cell being connected to a first word line; the body of each first memory cell being connected to a first body line; wherein each first memory cell is used for storing a data bit, and each first memory cell is capable of generating a current corresponding to the data bit, the current flowing across the drain of the first memory cell and the source of the first memory cell when a voltage at the first word line is an access voltage;
a plurality of second memory cells; each second memory cell having a gate, a body, a source, and a drain; the gate of each second memory cell being connected to a second word line; the body of each second memory cell being connected to a second body line; wherein each second memory cell is used for storing a data bit, the first memory cell is capable of generating a current corresponding to the data bit, the current flowing across the drain of the second memory cell and the source of the second memory cell when a voltage at the second word line is the access voltage;
a source circuit connected to the sources of the plurality of the first memory cells and to sources of the plurality of the second memory cells for making voltages at the sources of the plurality of the first memory cells equal voltages at the sources of the plurality of the second memory cells;
the method comprising:
making a voltage at the first body line differ from a voltage at the second body line.

14. The method of claim 13 further comprising:
setting a voltage at a drain of the first memory cell to be a predetermined voltage when a voltage at the first word line equals the access voltage, and then determining the data bit stored in the first memory cell when a voltage at the drain of the first memory cell is close to a voltage at the source of the first memory cell.

15. The method of claim 14 furthering comprising:
setting a voltage at the source of the first memory cell to be less than the predetermined voltage when a voltage at the drain of the first memory cell equals the predetermined voltage.

16. The method of claim 13 further comprising:
setting a voltage at a source of a first memory cell to be a predetermined voltage when a voltage at the first word line equals the access voltage and then determining the data bit stored in the first memory cell when a voltage at the drain of the first memory cell is close to a voltage at the source of the first memory cell.

17. The method of claim 16 further comprising:
setting a voltage at the drain of the first memory cell to be less than the predetermined voltage when the voltage at the source of the first memory cell equals the predetermined voltage.

18. The method of claim 13 wherein the drain of the first memory cell is connected to the drain of the second memory cell.

19. The method of claim 13 wherein a voltage at the first body line is greater than a voltage at the second body line when a voltage at the first word line equals the access voltage.

20. A method for controlling a memory; the memory comprising:
a plurality of first memory cells; each first memory cell having a gate, a body, a source, and a drain; the gate of each first memory cell being connected to a first word line; the body of each first memory cell being connected to a first body line; wherein each first memory cell is used for storing a corresponding data bit;
wherein when a voltage at the gate of the first memory cell equals a program voltage, the first memory stores a charge corresponding to the data bit of the first memory cell, and when a voltage at the first word line is an access voltage the first memory generatesa current corresponding to the data bit, the current flowing across the drain of the first memory cell and the source of the first memory cell;
a plurality of second memory cells; each second memory cell having a gate, a body, a source, and a drain; the gate of each second memory cell being connected to a second word line; the body of each second memory cell being connected to a second body line; wherein each second memory cell is used for storing a data bit; wherein when a voltage at the gate of the second memory cell equals the program voltage, the second memory cell stores a charge corresponding to the data bit of the second memory cell, and when a voltage at the second word line is the access voltage, the second memory cell generates a current corresponding to the data bit, the current flowing across the drain of the second memory cell and the source of the second memory cell;
a source circuit connected to the sources of the plurality of the first memory cells and to the sources of the plurality of the second memory cells for making a voltage at the source of each first memory cell equal a voltage at the source of the corresponding second memory cell;
the method comprising:
setting a voltage at the first body line to differ from a voltage at the second body line.

21. The method of claim 20 further comprising:
setting a voltage at the first body line to be negative and to be less than the program voltage when a voltage at the first word line is the program voltage.

22. The method of claim 20 further comprising:
setting a voltage at the source of each first memory cell to range from the program voltage to a voltage at the first body line when a voltage at the first word line equals the program voltage.

23. The method of claim 20 further comprising:
setting a voltage at the drain of the first memory cell to be greater than a voltage at the source of the first memory cell, so as to conduct a current flowing across the drain of the first memory cell and the source of the first memory cell to store a charge corresponding to the data bit of the first memory cell when a voltage at the first word line equals the program voltage.

24. The method of claim 20 wherein when a voltage at the gate of each first memory cell equals an erase voltage, each first memory cell is capable of moving out a charge corresponding to the first memory cell; the method further comprising:
setting a voltage at the first body line to equal a voltage at the source of each first memory cell when a voltage at the first word line equals the erase voltage.

25. The method of claim 20 wherein when a voltage at the gate of each first memory cell equals an erase voltage, each first memory cell is capable of moving out a charge corresponding to the first memory cell; the method further comprising:
setting a voltage at the first body line to be less than a voltage at the source of each first memory cell when a voltage at the first word line equals the erase voltage.
